(19) United States
(12) Patent Application Publication
(10) Pub. No.: US 2012/0068220 A1
(43) Pub. Date: Mar. 22, 2012

(54) REVERSE CONDUCTING-INSULATED GATE BIPOLAR TRANSISTOR

(75) Inventors: Toshiaki KOBAYASHI, Hyogo-ken (JP); Masakazu Kobayashi, Hyogo-ken (JP)

(73) Assignee: Kabushiki Kaisha Toshiba, Tokyo (JP)

(21) Appl. No.: 13/235,154

(22) Filed: Sep. 16, 2011

(30) Foreign Application Priority Data
Sep. 21, 2010 (JP) P2010-211009

(51) Int. Cl. H01L 29/747

(52) U.S. Cl. 257/124; 257/E29.215

(57) ABSTRACT

According to one embodiment, in a reverse conducting-insulated gate bipolar transistor, the buffer layer is provided on the backside of the second base layer, has a higher impurity concentration in comparison with the second base layer. The first collector layer is in contact with a portion of the backside of the buffer layer, has a higher impurity concentration in comparison with the second base layer. The second collector layer is in contact with a portion of the backside of the buffer layer, is provided so as to surround the first collector layer, has a higher impurity concentration in comparison with the first base layer. The third collector layer is in contact with a portion of the backside of the buffer layer, is provided so as to surround the second collector layer, has a higher impurity concentration in comparison with the second collector layer.

### CROSS REFERENCE TO RELATED APPLICATION

This application is based upon and claims the benefit of priority from the prior Japanese Patent Application No. 2010-211009, filed on Sep. 21, 2010, the entire contents of which are incorporated herein by reference.

### FIELD

Embodiments described herein relate to a reverse conducting-insulated gate bipolar transistor.

### BACKGROUND

A large number of insulated gate bipolar transistors (IGBT) are used as consumer and industrial power elements. A reverse conducting-IGBT (RC-IGBT) is attracting attention as a technology to reduce a turn-on loss (switching loss).

In the RC-IGBT, there is a trade-off between a snap-back of the IGBT and an on-voltage of a diode, restricting the design of the RC-IGBT, and a reduction of the on-voltage of the diode and improvement of the snap-back are further demanded.

### BRIEF DESCRIPTION OF THE DRAWINGS

FIG. 1 is a sectional view showing an RC-IGBT according to a first embodiment;

FIG. 2 is a plan view when the RC-IGBT according to the first embodiment is viewed from a collector side;

FIG. 3 is a sectional view showing the RC-IGBT of a comparative example according to the first embodiment;

FIG. 4 is a schematic diagram showing an operation of the RC-IGBT according to the first embodiment;

FIG. 5 is a diagram showing a relationship between a collector-emitter voltage and a collector current according to the first embodiment;

FIG. 6 is a diagram showing the relationship between a forward voltage and a forward current according to the first embodiment;

FIG. 7 is a plan view showing a modification of the RC-IGBT;

FIG. 8 is a sectional view showing the RC-IGBT according to a second embodiment; and

FIG. 9 is a schematic diagram showing the operation of the RC-IGBT according to the second embodiment.

### DETAILED DESCRIPTION

According to one embodiment, a reverse conducting-insulated gate bipolar transistor is provided with a second base layer, a buffer layer, a first collector layer, a second collector layer, a third collector layer, and a collector electrode. The second base layer is provided on a second principal surface opposite to a first principal surface of a first base layer of a first conductive type and is of a second conductive type. The buffer layer is provided on the second principal surface opposite to the first principal surface of the second base layer, has a higher impurity concentration in comparison with the second base layer, and is of the second conductive type. The first collector layer is in contact with a portion of the second principal surface opposite to the first principal surface of the buffer layer, has a higher impurity concentration in comparison with the second base layer, and is of the second conductive type. The second collector layer is in contact with a portion of the second principal surface opposite to the first principal surface of the buffer layer, is provided so as to surround the first collector layer, has a higher impurity concentration in comparison with the first base layer, and is of the first conductive type. The third collector layer is in contact with a portion of the second principal surface opposite to the first principal surface of the buffer layer, is provided so as to surround the second collector layer, has a higher impurity concentration in comparison with the second collector layer, and is of the first conductive type. The collector electrode is connected to the second principal surface opposite to the first principal surface of the first to third collector layers in contact with the buffer layer.

Hereinafter, further, a plurality of embodiments will be described below with reference to the drawings. The same reference numerals in the drawings show the same or similar portions.

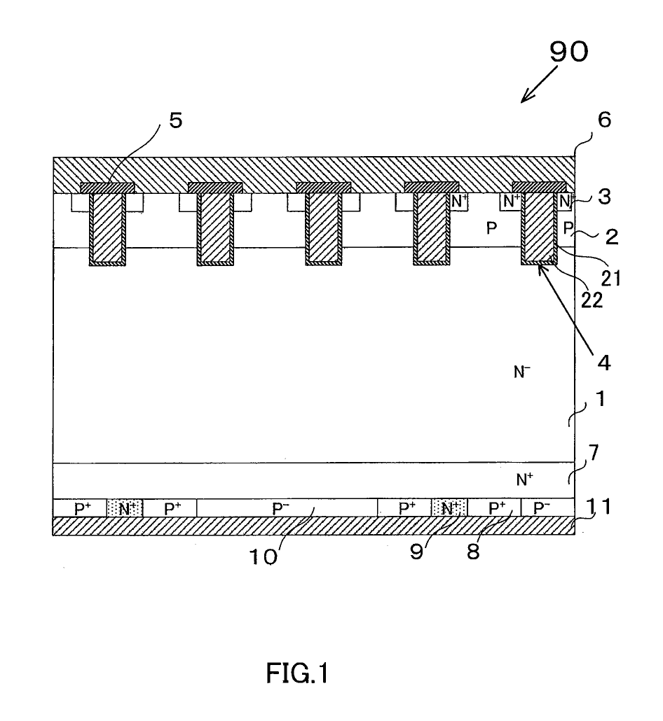

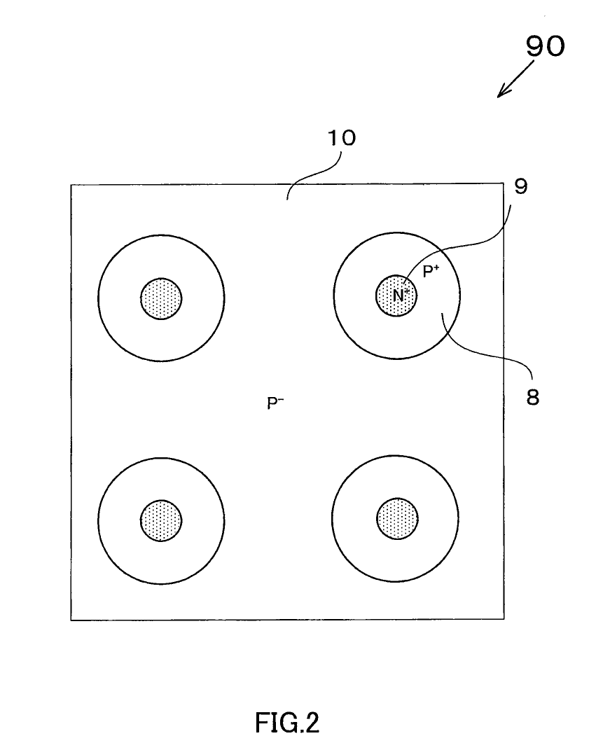

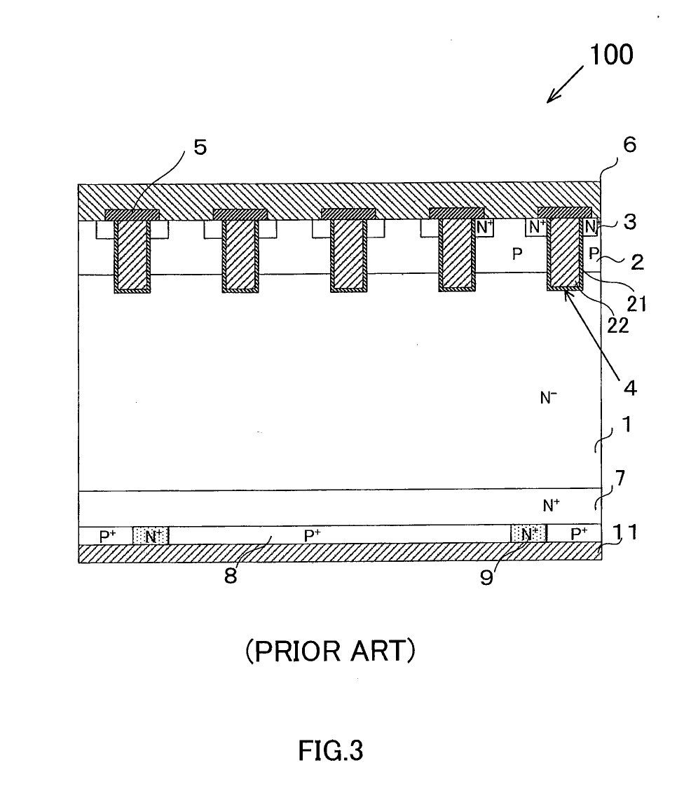

A reverse conducting-insulated gate bipolar transistor according to the first embodiment will be described with reference to the drawings. FIG. 1 is a sectional view showing an RC-IGBT. FIG. 2 is a plan view when the RC-IGBT is viewed from a collector side. FIG. 3 is a sectional view showing the RC-IGBT of a comparative example. In the embodiment, the on-voltage of the RC-IGBT is reduced by providing a P⁻ collector layer inside a P⁺ collector layer.

As shown in FIG. 1, an RC-IGBT 90 is a reverse conducting-insulated gate bipolar transistor having a trench gate structure buried in the surface of a semiconductor substrate. The RC-IGBT 90 is also called a collector short-insulated gate bipolar transistor and is used as a consumer and industrial power element.

In the RC-IGBT 90, a P base layer 2 is provided in the first principal surface (front side) of an N⁻ base layer 1 as a semiconductor substrate. An N⁺ emitter layer 3 having a higher impurity concentration in comparison with the N⁻ base layer 1 is selectively provided in the first principal surface (front side) of the P base layer 2. A trench 4 is formed by penetrating the N⁺ emitter layer 3 and the P base layer 2 to reach the surface of the N⁻ base layer 1. A gate insulating film 21 and a gate electrode 22 are buried in the trench 4. A trench gate is comprised with the gate insulating film 21 and the gate electrode 22.

An insulating film 5 is formed on the P base layer 2, the gate insulating film 21, and the gate electrode 22. The insulating film 5 has an opening (not shown) formed therein. An emitter electrode 6 electrically connected to the P base layer 2 and the N⁺ emitter layer 3 is provided in the opening and on the insulating film 5.

An N⁺ buffer layer 7 having a higher impurity concentration in comparison with the N⁻ base layer 1 is provided on the second principal surface (back side) opposite to the first principal surface (front side) of the N⁻ base layer 1. An N⁺ collector layer 9 having a higher impurity concentration in comparison with the N⁻ base layer 1 is provided in contact with a portion of the second principal surface (back side) opposite to the first principal surface (front side) of the N⁺ buffer layer 7.

A P⁺ collector layer 8 having a higher impurity concentration in comparison with the P base layer 2 is provided in contact with a portion of the second principal surface (back side) opposite to the first principal surface (front side) of the N⁺ buffer layer 7 so as to surround the N⁺ collector layer 9.

A P⁻ collector layer 10 having a lower impurity concentration in comparison with the P base layer 2 is provided in contact with a portion of the second principal surface (back side) opposite to the first principal surface (front side) of the N⁺ buffer layer 7 so as to surround the P⁺ collector layer 8.

The collector electrode 11 electrically connected to the second principal surface (back side) opposite to the first principal surface (front side) of the P⁺ collector layer 8, the N⁺ collector layer 9, and the P⁻ collector layer 10.

The spacing between the N⁺ collector layers 9 is set wider the spacing between the adjacent trench gates.

In the embodiment, names of the collector and emitter are adopted in the RC-IGBT, but the collector is also called a drain or an anode. The emitter is also called a source or a cathode.

In the RC-IGBT 90 viewed from the collector side, as shown in FIG. 2, the N⁺ collector layer 9 and the P⁺ collector layer 8 having a circular shape are periodically formed in the P⁻ collector layer 10. The N⁺ collector layer 9 is provided with the inner side and the P⁺ collector layer 8 is provided with the outer side.

A relationship between an exclusive area Scl1 of the N⁺ collector layer 9, an exclusive area Scl2 of the P⁺ collector layer 8, and an exclusive area Scl3 of the P⁻ collector layer 10 is set as follows,

Scl1<Scl2<Scl3 Formula (1)

In an RC-IGBT 100 of the comparative example, as shown in FIG. 3, the P⁻ collector layer 10 of the RC-IGBT 90 in the embodiment is not provided and instead, the P⁺ collector layer 8 is provided in the region of the P⁻ collector layer 10. The spacing between the N⁺ collector layers 9 is set wider in comparison with the embodiment. Otherwise, the RC-IGBT 100 of the comparative example has the same structure as the structure of the RC-IGBT 90.

The P⁻ collector layer 10 is provided with the RC-IGBT 90 in the embodiment. Advantages of providing the P⁻ collector layer 10 include as follows,

(1) Reduction of a built-in potential of a pn diode formed of the N⁺ buffer layer 7 and the P⁻ collector layer 10
(2) Reduction of the on-voltage of a low-current region of the RC-IGBT
(3) Suppression of the snap-back of the RC-IGBT
(4) Improvement of the forward voltage (Vf characteristics)
(A wider area of the N⁺ collector layer 9 and narrowing the spacing between the N⁺ collector layers 9 can be accomplished in accordance with suppression of the snap-back. Accordingly, it is possible to improve the forward voltage.)

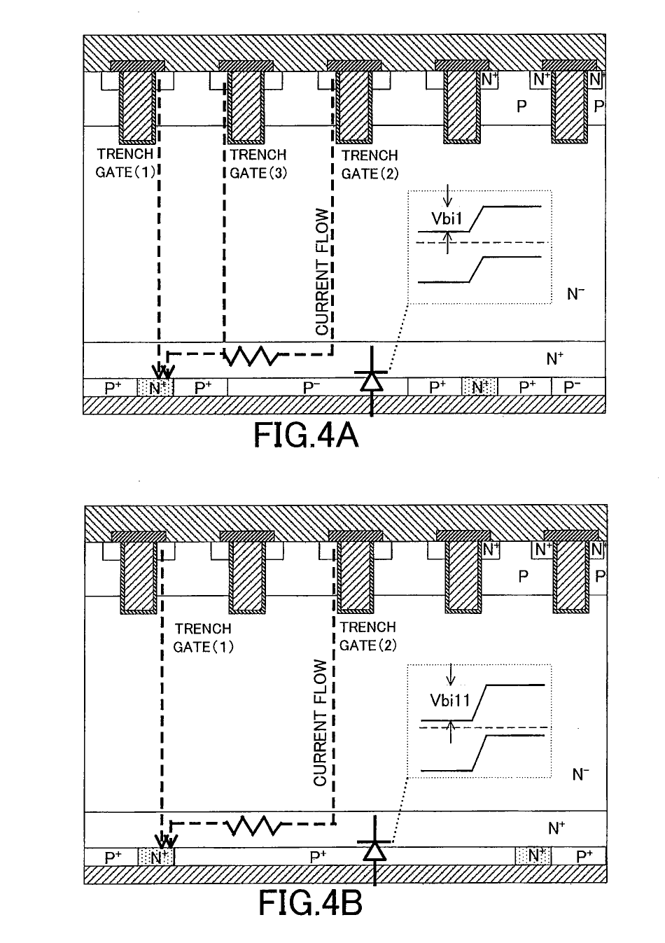

Advantages of providing the P⁻ collector layer 10 will be described based on a concrete operation of the RC-IGBT with reference to FIGS. 4 to 6. FIG. 4A is a schematic diagram showing the operation of the RC-IGBT in the embodiment and FIG. 4B is a schematic diagram showing the operation of the RC-IGBT of the comparative example.

As shown in FIG. 4B, a built-in potential Vbi11 of a pn diode formed of the N⁺ buffer layer 7 and the P⁺ collector layer 8 in the RC-IGBT 100 of the comparative example has a relatively large value because the N⁺ buffer layer 7 and the P⁺ collector layer 8 have a high impurity concentration. A snap-back occurs when the built-in potential Vbi11 is exceeded.

A trench gate (1) over the N⁺ collector layer 9 and a trench gate (2) over the P⁺ collector layer 8 will be considered. First, the trench gate (1) over the N⁺ collector layer 9 is turned on to pass a collector current of the RC-IGBT 100. When the potential of the N⁺ buffer layer 7 exceeds the built-in potential Vbi11 of the pn diode, the diode operates to function as an IBGT, and then, the trench gate (2) is turned on to pass the collector current of the RC-IGBT 100. The trench gate (2) has a longer distance to the N⁺ collector layer 9 in comparison with the trench gate (1), accordingly, a negative resistance component of the N⁺ buffer layer 7 is added in the trench gate (2).

Therefore, the trench gate (2) becomes a source (addition of a negative resistance component) of snap-back.

On the other hand, as shown in FIG. 4A, the RC-IGBT 90 of the embodiment includes, a built-in potential Vbi1 of a pn diode formed of the N⁺ buffer layer 7 and the P⁻ collector layer 10 and the built-in potential Vbi11 of a pn diode formed of the N⁺ buffer layer 7 and the P⁺ collector layer 8.

The region of the built-in potential Vbi1 formed of the N⁺ buffer layer 7 and the P⁻ collector layer 10 is set larger than the region of the built-in potential Vbi11 formed of the N⁺ buffer layer 7 and the P⁺ collector layer 8, and the relationship between the built-in potential Vbi1 and the built-in potential Vbi11 is set as follows,

Vbi1<Vbi11 Formula (2)

The trench gate (1) over the N⁺ collector layer 9, a trench gate (3) over the P⁺ collector layer 8, and the trench gate (2) over the P⁻ collector layer 10 will be considered. First, the trench gate (1) over the N⁺ collector layer 9 is turned on to pass a collector current of the RC-IGBT 90. Next, the built-in potential Vbi1 of a pn diode immediately below the trench gate (2) is lower than the built-in potential Vbi11 of a pn diode immediately below the trench gate (3) and thus, the trench gate (2) passes the collector current of the RC-IGBT 90 with the diode operating to function as an IBGT when the potential of the N⁺ buffer layer 7 exceeds the built-in potential Vbi11 of the pn diode. Subsequently, when the potential of the N⁺ buffer layer 7 exceeds the built-in potential Vbi11 of the pn diode, the diode operates to function as an IBGT and the trench gate (3) passes the collector current of the RC-IGBT 90.

Thus, a negative resistance component can significantly be reduced in the RC-IGBT 90.

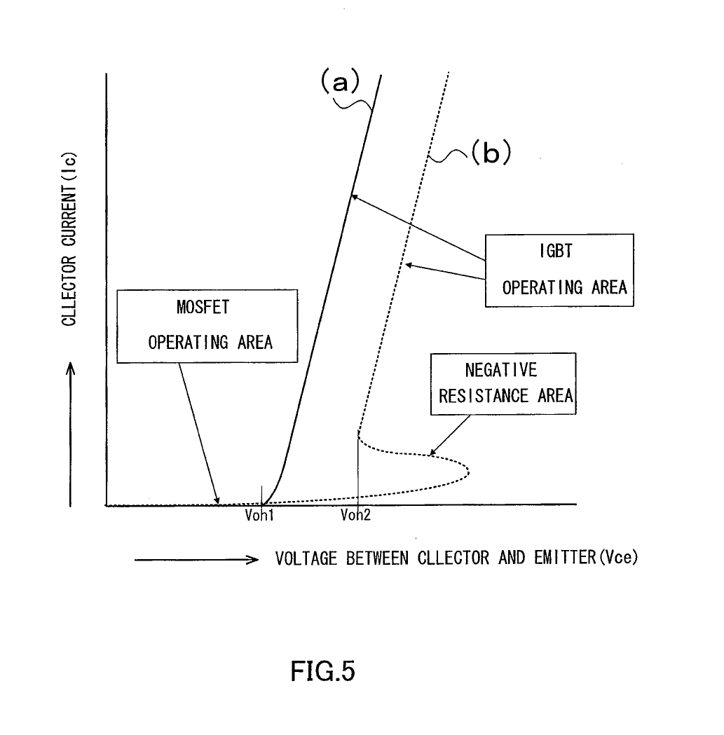

FIG. 5 is a diagram showing a relationship between a collector-emitter voltage and a collector current, a solid line (a) in FIG. 5 denotes the relationship of the embodiment, and broken line (b) denotes the relationship of the comparative example.

In the RC-IGBT 100 of the comparative example, as shown in FIG. 5B, when voltages are applied to between the collector and emitter and to the gate, the trench (1) as an MOSFET over the N⁺ collector layer 9 is first turned on to pass a collector current of the RC-IGBT 100. Since the region area of the trench gate (1) is small in the whole RC-IGBT 100, the current level of the collector current is low.

Next, a collector current of the trench gate separated from the N⁺ collector layer 9 and occupying most of the region of the RC-IGBT 100 contributes as a collector current of the RC-IGBT 100. In this case, a negative resistance component of the N⁺ buffer layer 7 is added so that a snap-back occurs. The effect of the negative resistance component is reduced and all trench gates of the RC-IGBTs 100 operate as IGBTs (after an on-voltage Von2).

On the other hand, in the RC-IGBT 90 of the embodiment, as shown in FIG. 5A, when voltages are applied to between the collector and emitter and to the gate, the trench gate (1) as an MOSFET over the N⁺ collector layer 9 is first turned on to pass a collector current of the RC-IGBT 90. Next, the built-in potential Vbi1 is lower than the built-in potential Vbi11 and thus, a collector current of a trench gate over the P⁻ collector layer 10 separated from the N⁺ collector layer 9 contributes as a collector current of the RC-IGBT 90. Subsequently, a collector current of a trench gate over the P⁺ collector layer 8 contributes as a collector current of the RC-IGBT 90.

Thus, in the RC-IGBT 90, the negative resistance component can significantly be reduced, so that the snap-back can be suppressed. Moreover, the on-voltage in the low-current region can be reduced (on-voltage Von2 [symbol] on-voltage Von1).

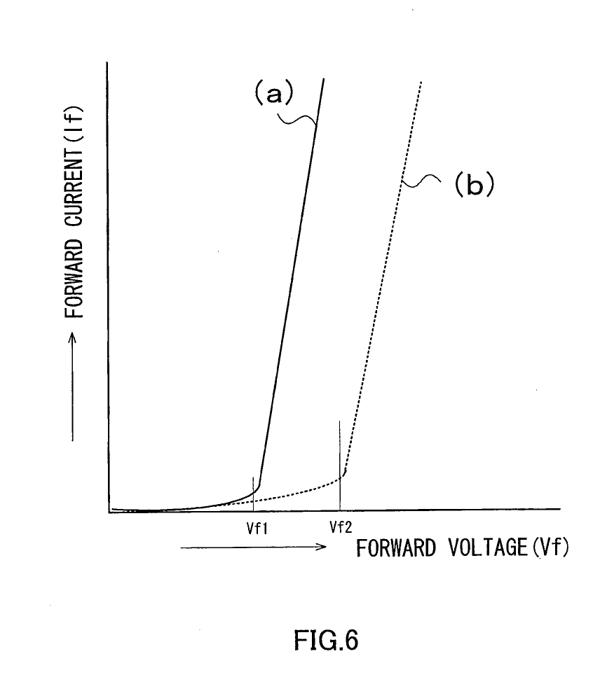

FIG. 6 is a diagram showing the relationship between a forward voltage and a forward current, a solid line (a) in FIG. 6 denotes the relationship of the embodiment, and broken line (b) denotes the relationship of the comparative example.

As shown in FIG. 6, it is necessary to set a forward voltage Vf2 to a relatively large value in the RC-IGBT 100 of the comparative example. The reason is not possible to make the exclusive area wider by narrowing the spacing of the N⁺ collector layers 9 so as to suppress the snap-back.

On the other hand, in the RC-IGBT 90 of the embodiment, a forward voltage Vf1 can be made lower in comparison with the RC-IGBT 100 of the comparative example. This is because the snap-back is suppressed so that the spacing of the N⁺ collector layers 9 can be made narrower and the exclusive area can be made wider.

As described above, in a reverse conducting-insulated gate bipolar transistor in the embodiment, the N⁺ buffer layer 7 is provided on the back side of the N⁻ base layer 1. The N⁺ collector layer 9 in contact with a portion of the back side of the N⁺ buffer layer 7 is provided. The P⁺ collector layer 8 is provided in contact with a portion of the back side of the N⁺ buffer layer 7 so as to surround the N⁺ collector layer 9. The P⁻ collector layer 10 is provided in contact with a portion of the back side of the N⁺ buffer layer 7 so as to surround the P⁺ collector layer 8. The collector electrode 11 electrically connected to the back side of the P⁺ collector layer 8, the N⁺ collector layer 9, and the P⁻ collector layer 10 is provided.

Thus, the on-voltage in the low-current region can be reduced. Moreover, the negative resistance component can be reduced and the snap-back can be suppressed. Further, the area of the N⁺ collector layer 9 can be increased, so that Vf characteristics can be improved.

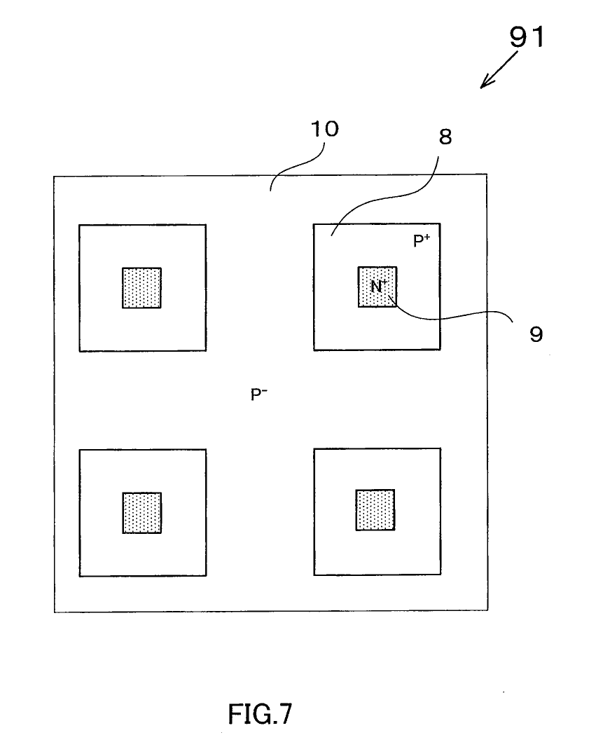

In the embodiment, the P⁺ collector layer 8 and the N⁺ collector layer 9 are formed in a circular shape, but the embodiment is not limited to the circular shape. The P⁺ collector layer 8 and the N⁺ collector layer 9 may be formed in an n-polygonal shape (n is an integer equal to 3 or greater). As shown in the RC-IGBT 91 in FIG. 7, for example, the P⁺ collector layer 8 and the N⁺ collector layer 9 may be formed in a rectangular shape.

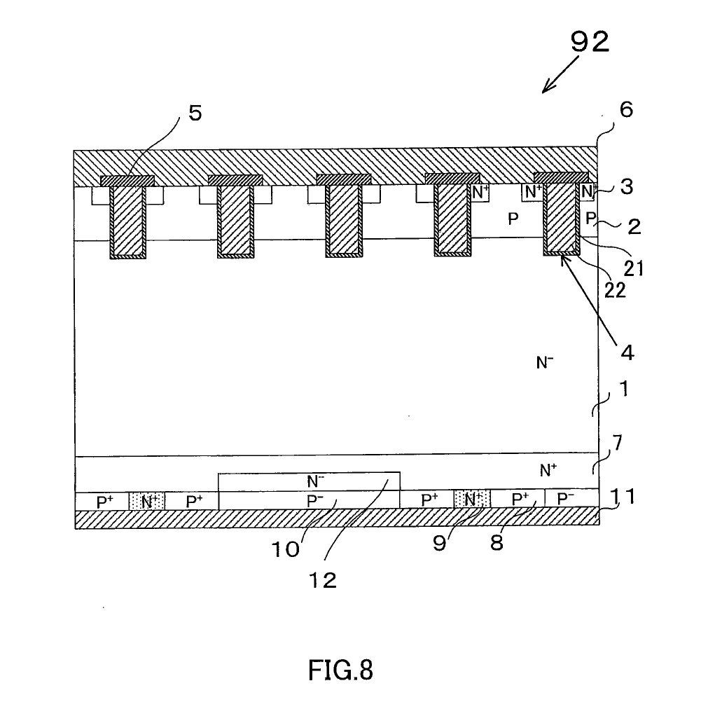

A reverse conducting-insulated gate bipolar transistor according to the second embodiment will be described with reference to drawings. FIG. 8 is a sectional view showing the RC-IGBT. In the embodiment, an N⁻ collector layer is provided on a P⁻ collector layer to reduce the on-voltage of the RC-IGBT.

The same reference numerals are attached to the same structural portions as those in the first embodiment and a description of such portions is omitted to describe only different portions.

As shown in FIG. 8, an RC-IGBT 92 is a reverse conducting-insulated gate bipolar transistor having a trench gate structure buried in the surface of a semiconductor substrate. The RC-IGBT 92 is used as a consumer and industrial power element.

In the RC-IGBT 92, the N⁺ buffer layer 7 having a higher impurity concentration in comparison with the N⁻ base layer 1 is provided on the second principal surface (back side) opposite to the first principal surface (front side) of the N⁻ base layer 1. An N⁻ collector layer 12 is provided on the second principal surface (back side) opposite to the first principal surface (front side) of, the N⁺ buffer layer 7. The N⁺ collector layer 12 has a lower impurity concentration in comparison with the N⁺ buffer layer 7. The N⁺ collector layer 9 having a higher impurity concentration in comparison with the N⁻ base layer 1 is provided in contact with a portion of the second principal surface (back side) opposite to the first principal surface (front side) of the N⁺ buffer layer 7. The P⁺ collector layer 8 having a higher impurity concentration in comparison with the P base layer 2 is provided in contact with a portion of the second principal surface (back side) opposite to the first principal surface (front side) of the N⁺ buffer layer 7 so as to surround the N⁺ collector layer 9.

The P⁻ collector layer 10 having a lower impurity concentration in comparison with the P base layer 2 is provided in contact with a portion of the second principal surface (back side) opposite to the first principal surface (front side) of the N⁻ collector layer 12 so as to surround the P⁺ collector layer 8.

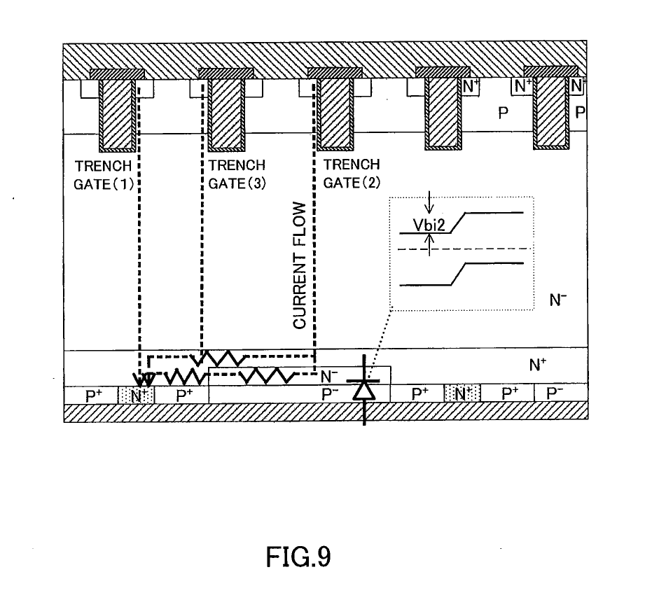

Next, the operation of the RC-IGBT will be described with reference to FIG. 9. FIG. 9 is a schematic diagram showing the operation of the RC-IGBT.

As shown in FIG. 9, the RC-IGBT 92 of the embodiment includes a built-in potential Vbi2 of a pn diode formed of the N⁻ collector layer 12 and the P⁻ collector layer 10 and the built-in potential Vbi11 of a pn diode formed of the N⁺ buffer layer 7 and the P⁺ collector layer 8.

The region of the built-in potential Vbi2 formed of the N⁻ collector layer 12 and the P⁻ collector layer 10 is set larger than the region of the built-in potential Vbi11 formed of the N⁺ buffer layer 7 and the P⁺ collector layer 8, and the relationship between the built-in potential Vbi2, the built-in potential Vbi11, and the built-in potential Vbi1 is set as follows,

Vbi2<Vbi1<Vbi11 Formula (3)

The relationship between an exclusive area Scl1 of the N⁺ collector layer 9, an exclusive area Scl2 of the P⁺ collector layer 8, an exclusive area Scl3 of the P⁻ collector layer 10, and an exclusive area Scl4 of the N⁻ collector layer 12 is set as follows,

Scl1<Scl2<Scl3≦Scl4 Formula (4)

The relationship of the trench gate (1) over the N⁺ collector layer 9, the trench gate (2) over the P⁺ collector layer 8, and the trench gate (3) over the P⁻ collector layer 10 will be considered. When voltages are applied to between the collector and emitter and to the gate, first, the trench gate (1) over the N⁺ collector layer 9 is turned on to pass a collector current of the RC-IGBT 92. Next, the built-in potential Vbi2 of a pn diode immediately below the trench gate (2) is lower than the built-in potential Vbi11 of a pn diode immediately below the trench gate (3) and thus, the trench gate (2) passes a collector current of the RC-IGBT 92 with the diode operating to function as an IBGT when the potential of the N⁻ collector layer 12 exceeds the built-in potential Vbi2 of the pn diode. Subsequently, when the potential of the N⁺ buffer layer 7 exceeds the built-in potential Vbi11 of the pn diode, the diode operates to function as an IBGT and the trench gate (3) passes the collector current of the RC-IGBT 92.

Thus, in the RC-IGBT 92, the negative resistance component can significantly be reduced, so that the snap-back can be suppressed. Moreover, the on-voltage can be reduced. Since the snap-back is suppressed, the spacing of the N⁺ collector layers 9 can be made narrower and the exclusive area of the N⁺ collector layer 9 can be increased, so that Vf characteristics can also be improved.

As described above, in a reverse conducting-insulated gate bipolar transistor in the embodiment, the N⁺ buffer layer 7 is provided on the back side of the N⁻ base layer 1. The N⁻ collector layer 12 is provided on the back side of the N⁺ buffer layer 7. The N⁺ collector layer 9 in contact with a portion of the back side of the N⁺ buffer layer 7 is provided. The P⁺ collector layer 8 is provided in contact with a portion of the back side of the N⁺ buffer layer 7 so as to surround the N⁺ collector layer 9. The P⁻ collector layer 10 is provided in contact with a portion of the back side of the N⁻ collector layer 12 so as to surround the P⁺ collector layer 8.

Thus, the on-voltage in the low-current region can be reduced. Moreover, the negative resistance component can be reduced and the snap-back can be suppressed. Further, the area of the N⁺ collector layer 9 can be increased, so that Vf characteristics can be improved.

The invention is not limited to the above embodiments and may be modified in various ways without deviating from the scope of the invention.

In the first embodiment, the P⁻ collector layer 10 is provided on a side portion of the P⁺ collector layer 8, but the invention is not necessarily limited to this. Further, a P⁻⁻ collector layer may be provided on a side portion opposite to the P⁻ collector layer 8 of the P⁻ collector layer 10. In the second embodiment, the N⁻ collector layer 12 is provided on the P⁻ collector layer 10, but the invention is not necessarily limited to this. Further, an N⁻⁻ collector layer may be provided on a side portion opposite to the N⁺ buffer layer 7 of the N⁻ collector layer 12. While the invention is applied to trench gate type RC-IGBTs of the embodiments, the invention may also be applied to planar gate type RC-IGBTs.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A reverse conducting-insulated gate bipolar transistor, comprising:
a second base layer of a second conductive type provided on a second principal surface opposite to a first principal surface of a first base layer of a first conductive type;
a buffer layer of the second conductive type provided on a second principal surface opposite to a first principal surface of the second base layer in contact with the first base layer, the buffer layer having a higher impurity concentration in comparison with the second base layer;
a first collector layer of the second conductive type to contact with a portion of a second principal surface opposite to a first principal surface of the buffer layer in contact with the second base layer, the first collector layer having the higher impurity concentration in comparison with the second base layer;
a second collector layer of a first conductive type to contact with a portion of the second principal surface of the buffer layer, the second collector layer provided so as to surround the first collector layer, and the second collector layer having the higher impurity concentration in comparison with the first base layer;
a third collector layer of the first conductive type to contact with a portion of the second principal surface of the buffer layer, the third collector layer provided so as to surround the second collector layer, and the third collector layer having the lower impurity concentration in comparison with the second collector layer; and
a collector electrode connected to a second principal surface opposite to a first principal surface of the first to third collector layers in contact with the buffer layer.

2. The reverse conducting-insulated gate bipolar transistor according to claim 1, wherein the first and second collector layers are provided periodically in the third collector layer.

3. The reverse conducting-insulated gate bipolar transistor according to claim 1, wherein the first and second collector layers have a circular shape or an n(n is an integer equal to 3 or greater)-polygonal shape.

4. The reverse conducting-insulated gate bipolar transistor according to claim 3, wherein an exclusive area of the second collector layer is larger than the exclusive area of the first collector layer, and the exclusive area of the third collector layer is larger than the exclusive area of the second collector layer.

5. The reverse conducting-insulated gate bipolar transistor according to claim 1, wherein a built-in potential constituted of the buffer layer and the second collector layer is larger than the built-in potential constituted of the buffer layer and the third collector layer.

6. The reverse conducting-insulated gate bipolar transistor according to claim 1, wherein spacing between the first collector layers is wider than gate spacing.

7. The reverse conducting-insulated gate bipolar transistor according to claim 1, wherein the first base layer has the higher impurity concentration in comparison with the third collector layer and the lower impurity concentration in comparison with the second collector layer.

8. The reverse conducting-insulated gate bipolar transistor according to claim 1, wherein the reverse conducting-insulated gate bipolar transistor is a trench gate type or a planar gate type reverse conducting-insulated gate bipolar transistor.

9. A reverse conducting-insulated gate bipolar transistor, comprising:
a second base layer of a second conductive type provided on a second principal surface opposite to a first principal surface of a first base layer of a first conductive type;
a buffer layer of the second conductive type provided on a second principal surface opposite to a first principal surface of the second base layer in contact with the first base layer, the buffer layer having a higher impurity concentration in comparison with the second base layer;
a first collector layer of the second conductive type to contact with a portion of a second principal surface opposite to a first principal surface of the buffer layer in contact with the second base layer, the first collector layer having the higher impurity concentration in comparison with the second base layer;
a second collector layer of a first conductive type to contact with a portion of the second principal surface of the buffer layer, the second collector layer provided so as to surround the first collector layer, and the second collector layer having the higher impurity concentration in comparison with the first base layer;
a third collector layer of the first conductive type to contact with a portion of the second principal surface of the buffer layer, the third collector layer provided so as to surround the second collector layer, and the third collector layer having the lower impurity concentration in comparison with the second collector layer;
a collector electrode connected to a second principal surface opposite to a first principal surface of the first to third collector layers in contact with the buffer layer; and
a fourth collector layer of a second conductive type to contact with the first principal surface of the third collector layer, the fourth collector layer having the lower impurity concentration in comparison with the first collector layer, and the fourth collector layer provided in the buffer layer.

10. The reverse conducting-insulated gate bipolar transistor according to claim 9, wherein the first and second collector layers are provided periodically in the third collector layer.

11. The reverse conducting-insulated gate bipolar transistor according to claim 9, wherein the first and second collector layers have a circular shape or an n(n is an integer equal to 3 or greater)-polygonal shape.

12. The reverse conducting-insulated gate bipolar transistor according to claim 11, wherein an exclusive area of the second collector layer is larger than the exclusive area of the first collector layer, the exclusive area of the third collector layer is larger than the exclusive area of the second collector layer, and the exclusive area of the fourth collector layer is equal to or larger than the exclusive area of the third collector layer.

13. The reverse conducting-insulated gate bipolar transistor according to claim 9, wherein a built-in potential constituted of the buffer layer and the second collector layer is larger than the built-in potential constituted of the buffer layer and the third collector layer, and the built-in potential constituted of the buffer layer and the third collector layer is larger than the built-in potential constituted of the third collector layer and the fourth collector layer.

14. The reverse conducting-insulated gate bipolar transistor according to claim 9, wherein spacing between the first collector layers is wider than gate spacing.

15. The reverse conducting-insulated gate bipolar transistor according to claim 9, wherein the first base layer has the higher impurity concentration in comparison with the third collector layer and the lower impurity concentration in comparison with the second collector layer.

16. The reverse conducting-insulated gate bipolar transistor according to claim 9, wherein the reverse conducting-insulated gate bipolar transistor is a trench gate type or a planar gate type reverse conducting-insulated gate bipolar transistor.
